(19) United States
(12) Patent Application Publication
(10) Pub. No.: US 2004/0139377 A1
(43) Pub. Date: Jul. 15, 2004

(54) METHOD AND APPARATUS FOR COMPACT SCAN TESTING

(75) Inventors: Carl F. Barnhart, Tucson, AZ (US); Robert W. Bassett, Essex Junction, VT (US); L. Owen Farnsworth III, Lincoln, VT (US); Brion L. Keller, Binghamton, NY (US); Bernd K.F. Koenemann, San Jose, CA (US)

Correspondence Address: SCHMEISER, OLSEN + WATTS, SUITE 201, 3 LEAR JET, LATHAM, NY, 12033, US

(73) Assignee: International Business Machines Corporation, Armonk, NY

(21) Appl. No.: 10/248,352

(22) Filed: Jan. 13, 2003

(51) Int. Cl. G01R 31/28

(52) U.S. Cl. 714/726

(57) ABSTRACT

A method an apparatus for testing logic circuits containing a set of scan chains, each set of scan chains comprising a multiplicity of scan chains. The apparatus comprising: a scan input; a scan output; an input shift register coupled between the scan input and the set of scan chains, each first stage of different scan chains of the set of scan chains coupled to a different stage of the input shift register; and an output shift register coupled between the scan output and the set of scan chains, each last stage of different scan chains coupled to a different stage of the output shift register.

### BACKGROUND OF THE INVENTION

1. Field of the Invention

The present invention relates to the field of testing integrated circuits; more specifically, it relates to a method and an apparatus for testing integrated circuits using scan chains.

### BACKGROUND OF THE INVENTION

As the size and complexity of logic chips such as application specific integrated circuit (ASIC) chips grew, scan based testing was developed as an alternative to conventional testing in order to reduce test equipment time and costs. However, as the number logic gates have grown, even scan based testing has created several problems for automatic test equipment (ATE). A first problem is buffer overflow for ATEs with fixed size buffers. A second problem is insufficient data transfer bandwidth between the ATE and the product under test. A third problem, becoming increasingly important for low power applications such as used in portable devices and in aerospace applications, is power consumption requirements of the chip designs limit the maximum internal scan cycle rate for large dense complementary metal-oxide-silicon (CMOS) devices. A fourth problem is as ASICs grow in complexity and contain more functions, applications require more signal inputs and outputs (I/Os) and the number of I/Os left available for testing becomes limited.

Therefore, there is a need for a method of reducing the amount of test data to be stored, that increases the effective test rate within the constraints of limited bandwidth and is not limited by external data I/O bandwidth without exceeding internal chip design and power consumption constraints.

### SUMMARY OF THE INVENTION

A first aspect of the present invention is an apparatus for testing logic circuits containing a set of scan chains, comprising: a scan input; a scan output; an input shift register coupled between the scan input and the set of scan chains, each first stage of different scan chains of the set of scan chains coupled to a different stage of the input shift register; and an output shift register coupled between the scan output and the set of scan chains, each last stage of different scan chains coupled to a different stage of the output shift register.

As second aspect of the present invention is a method for testing logic circuits containing a set of scan chains, comprising: providing a scan input; providing a scan output; providing an input shift register coupled between the scan input and the set of scan chains, each first stage of different scan chains of the set of scan chains coupled to a different stage of the input shift register; and providing an output shift register coupled between the scan output and the set of scan chains, each last stage of different scan chains coupled to a different stage of the output shift register; writing a test pattern to the scan input; propagating the test pattern through the scan chains; and reading a resultant pattern at the scan output.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIG. 1 is a block diagram of a system for testing a logic device according to a first embodiment of the present invention;

FIG. 2 is a block diagram of a system for testing a logic device according to a second embodiment of the present invention;

FIGS. 3A and 3B are diagrams illustrating a load operation resulting in conflicting values of care bits;

FIGS. 4A and 4B are diagrams illustrating a load operation resulting in non-conflicting values of care bits;

FIG. 5 is a block diagram of a system for testing a logic device according to a third embodiment of the present invention;

FIG. 6 is a schematic diagram of an exemplary integral multiple input signature register logic/output shift register combination;

FIG. 7 is a schematic diagram of an exemplary integral linear feedback shift register logic/input shift register combination and a typical spreading network; and

FIG. 8 is a block diagram of a system for testing a logic device according to a modification of the first embodiment of the present invention.

### DETAILED DESCRIPTION OF THE INVENTION

For the purposes of the present invention, a stage of a register or a scan chain is defined to include one or more latches. These latches may include latch types such as flip-flops. A stage holds or latches a data bit. Even though a single clock may be described for each register or scan chain, it should be understood that multiple clock signals may be required by specific implementations of the present invention.

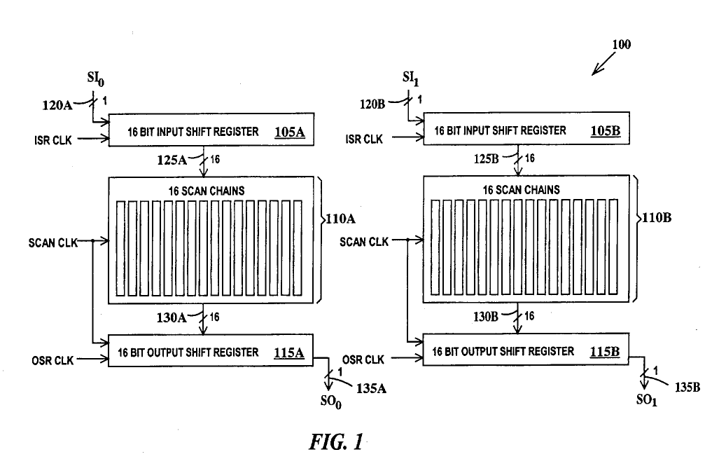

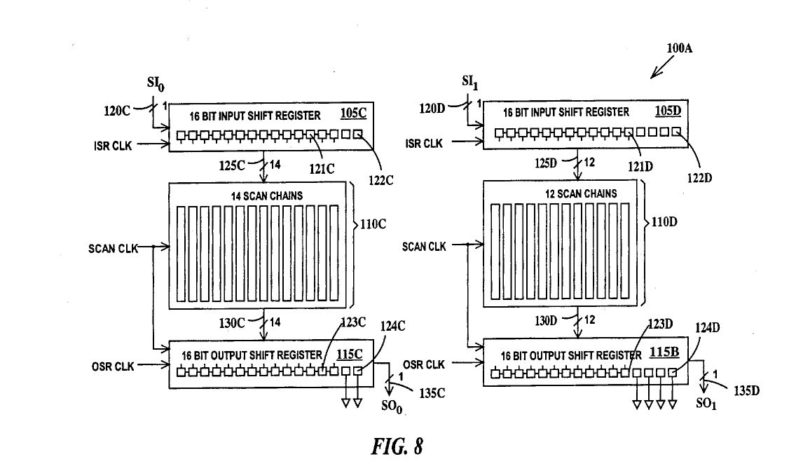

FIG. 1 is a block diagram of a system for testing a logic device according to a first embodiment of the present invention. In FIG. 1, test system 100 includes a first input shift register 105A, a first set of scan chains 110A and a first output shift register 115A. First input shift register 105A receives serial scan in data (SI0), which is a test pattern, from a first serial input line 120A. The number of first scan chains 110A is equal to the number of stages in first input shift register 105A. (See FIG. 8 and discussion infra for a case where the number of scan chains is less than the number of stages of the input and output shift registers.) Each stage of first input shift register 105A is coupled to a different first stage of a single scan chain 1110A via bus 125A. In the present example, first input shift register 105A comprises 16 stages (i.e. the first input shift register 105A is a 16-bit register) and there are 16 scan chains 110A and bus 125A is 16 bits wide. The number of scan chains may be any number and the value of 16 is used only for exemplary purposes.

Each scan chain 110A, may include hundreds or thousands of stages arranged in series and coupled to the combinational logic of the integrated circuit being tested. (As is well known in the art, in practice each scan chain comprises an input scan chain and an output scan chain in parallel with a different set of combinational logic coupled to corresponding stages in the input and the output scan chains).

The number of stages in first output shift register 115A is equal to the number of first scan chains 110A. Each stage of first output shift register 115A is coupled to a different last stage of a single scan chain 1110A via a bus 130A. In the present example, first output shift register 115A comprises 16 stages (i.e. first output shift register 115A is a 16-bit register) and bus 130A is 16 bits wide. First output shift register 115A sends serial scan out data (SO0), which is the resultant test pattern after the test pattern passes through the combinational logic, to a first serial output line 135A. Thus, the sequential relationship between SI0 and SO0 is kept intact.

Movement of bits between stages of first input shift register 105A is controlled by a clock signal ISR CLK. Movement of bits between stages of first scan chains 1110A is controlled by a clock signal SCAN CLK. Movement of bits between stages of first output shift register 115A is controlled by a clock signal OSR CLK.

Test system 100 is operated, in the present example, in loops of 16 cycles. The number of cycles per loop is equal to the number of stages in first input and first output shift registers 105A and 115A. The number of loops is equal to the number of stages in first scan chains 110A. In the first cycle of each loop, all three clocks ISR CLK, SCAN CLK and OSR CLK are cycled once. This moves one bit into first input shift register 105A, one 16-bit word from the input shift register into the first stage of scan chains 110A (one bit per scan chain), and one 16-bit word out of the last stages of first scan chains 110A (one bit per scan chain) into first output shift register 115A. Next both the ISR CLK and OSR CLK are cycled 15 times which serially moves 15 new data bits into first input shift register 105A and serially moves 15 data bits out of first output shift register 115A. A feature of the present invention is that the frequency of the ISR and OSR CLK signals may be higher than the SCAN CLK frequency. The ISR and OSR frequency may be adjusted to match that of ATE while the SCAN CLK runs a lower, chip design frequency. In the present example, ISR CLK and OSR CLK could run 16 times faster than SCAN CLK. If each first scan chain 110A contains, for example, 1000 stages each, then 16,000 cycles (1000 loops of 16 cycles each) will be required to fully scan all 1000 stages of the 16 scan chains. Test system 100, runs in full scan mode.

Finally, it should be recognized that the very first scan clock cycle transfers old data from first input shift register 105A into first scan chains 110A and it may be desirable to continue testing for one extra loop (16 cycles) to shift the old data out of the last stages of first scan chains 110A and scan in new data before terminating the test operation.

Test system 100 may also include any number of additional groups of input shift registers, scan chain sets and output shift registers. A second such group is illustrated in FIG. 1. Test system 100 further includes a second input shift register 105B, a second set of scan chains 110B and a second output shift register 115B. Second input shift register 105B, second scan chains 110B (except for the number of scan chains which may be different) and second output shift register 115B are identical to and operate identically to first input shift register 105A, first scan chains 110A and first output shift register 115A, respectively. Second input shift register 105B receives serial scan in data (SI1) via a second serial input 120B. Second output shift register 115B sends serial scan out data (SO1) to a second serial output line 135B. Thus, the sequential relationship between SI1 and SO1 is kept intact.

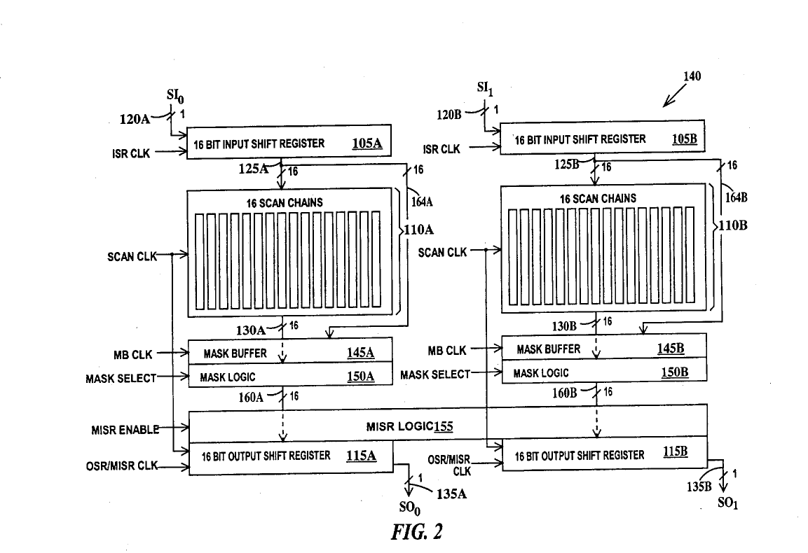

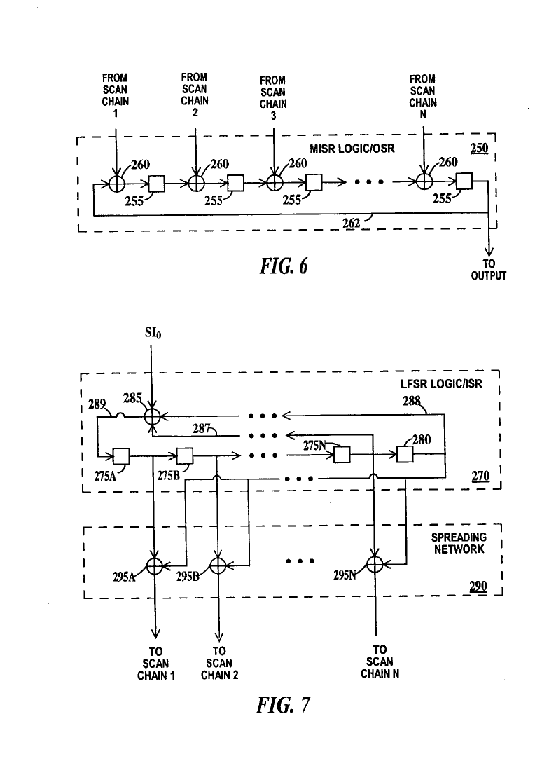

FIG. 2 is a block diagram of a system for testing a logic device according to a second embodiment of the present invention. In FIG. 2 a test system 140, includes (in addition to all the components of test system 100 illustrated in FIG. 1 and described supra) a first mask buffer 145A, a second mask buffer 145B, a first mask logic 150A, a second mask logic 150B and a multiple input signature register logic (MISR) 155. First mask buffer 145A and first mask logic 150A are coupled between first scan chains 110A and MISR logic 155. Second mask buffer 145B and second mask logic 150B are coupled between second scan chains 110B and MISR logic 155. MISR logic 155 is coupled to first output shift register 115A and second output shift register 115B. MISR logic 155, first output shift register 115A and second output shift register 115B are implemented integral to one another. An exemplary integral MISR logic/output shift register is illustrated in FIG. 6 and described infra.

First mask buffer 145A and second mask buffer 145B are identical and operate identically so only first mask buffer 145A will be described. The operation of mask buffers and mask logic is well known in the industry and will only be described briefly. First mask buffer 145A is capable of storing one or more mask words in one or more rows of stages. The number of stages in each set of stages is equal to the number of scan first chains 110A. The input of each stage (or input of each corresponding stage from a different row) of first mask buffer 145A is coupled to a single, different stage of first input shift register 105A by a bus 164A. This allows for loading of a pattern(s) into first mask buffer 145A by cycling clock signal MB CLK. The output of each stage (or outputs of each corresponding stage from a different row) of first mask buffer 145A is coupled to a single, different first input of a single different AND gate within first mask logic 150A. The number of AND gates is equal to the number of first scan chains 110A. The number of inputs to each AND gate is equal to the number of mask words stored in first mask buffer 145A plus one additional input. The additional input of each AND gate is coupled to the output of a single, different first scan chain 110A via bus 130A. First mask logic 150A also includes mask select circuits (not shown) to allow “ANDing” of no, one or multiple mask words with the data in first scan chains 110A. Movement of data from first mask buffer 145A/first mask logic 150A to MISR 155 is under the control of MB CLK.

The output of each AND gate of first mask logic 150A (or of each first scan chain 110A if masking is not enabled) is coupled to a single, different gate in MISR logic 155 via a bus 160A. MISR logic 155 in conjunction with first and second output shift registers 115A and 115B, selectively concatenate and compresses the outputs of first and second mask logic 150A and 150B onto serial output lines 135A and 135B. Movement of data though MISR logic 155 and first output shift register 115A to serial output line 135A is under the control of under the control of a OSR/MISR logic CLK. MISR logic 155 may be bypassed by a MISR ENABLE signal. The masks applied by first mask logic 150A and second mask logic 150B may be changed or the masking operation disabled by a MASK SELECT signal.

Test system 140 runs in compressed data mode and the output of MISR logic logic 155 is not true test result data (as in test system 100 of FIG. 1) but a signature representing the data bits of each word read out of first and second scan chains 110A and 110B. However, since each time a word is written out of first and second scan chains 115A and 115B failing bit information may be overwritten. MISR logic 155, by “XORing” each old bit in a MISR stage with the corresponding new bit from the last stages of each first scan chain 110A captures that information.

In the present example, each compressed scan operation begins with 16 prefix cycles to load first and second input shift registers 105A and 105B to a fixed initial state and to unload the last MISR signature accumulated by the last compressed scan operation from first and second output shift registers 115A and 115B. This is accomplished by cycling ISR CLK and OSR/MISR CLK 16 times with MISR logic 155 disabled (MISR ENABLE=off) and SCAN CLK low (off). SI0 and SI1 are tied to fixed constant values during these first 16 cycles.

In the example of each first scan chain 110A having 1000 stages, MISR logic 155 is next enabled (MISR ENABLE=on) and 1000 ISR CLK, SCAN CLK and OSR/MISR CLK simultaneous cycles are applied. There is one simultaneous ISR CLK, SCAN CLK and OSR/MISR CLK cycle applied for each first scan chain 110A stage. If first and second inputs 120A and 120B and first and second outputs 135A and 135B are bidirectional, first and second inputs 120A and 120B are held in the input mode and first and second outputs 135A and 135B are held in the output mode. Input states on first and second inputs 120A and 120B are applied for each cycle. Each of these cycles accumulates two 16-bit words from first and second scan chains 110A and 110B into MISR logic 155 and transfers the current contents of first and second input shift registers 105A and 105B into scan first and second chains 110A and 110B respectively, while first and second input shift registers 105A and 105B, MISR logic 155, first and second scan chains 110A and 110B and first and second output shift registers 115A and 115B are each shifted by one bit position.

If this is the last compressed operation, then 16 prefix cycles to unload the last MISR signature from first and second output shift registers 115A and 115 are required. This is accomplished by simultaneous cycling of ISR CLK and OSR/MISR CLK 16 times with MISR logic 155 disabled (MISR ENABLE=off) and SCAN CLK low (off). SI0 and SI1 are tied to fixed constant values during these last 16 cycles. Thus, a complete test requires 1032 cycles as compared to the 16,000 cycles required for test system 100 of FIG. 1.

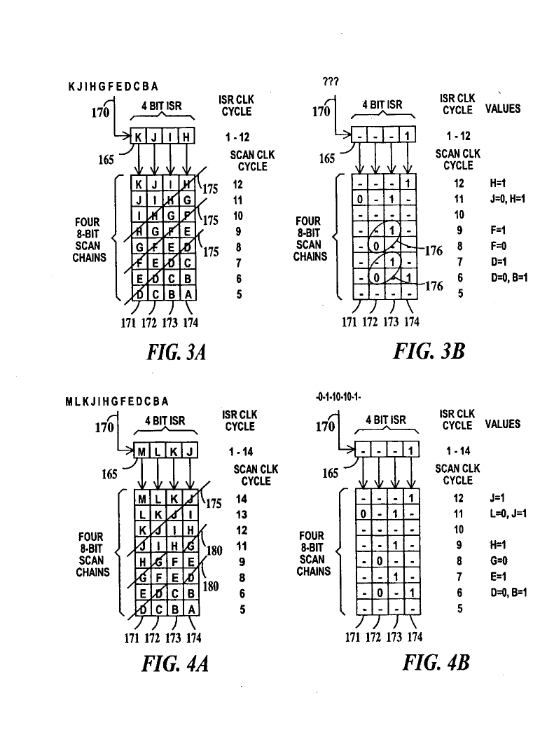

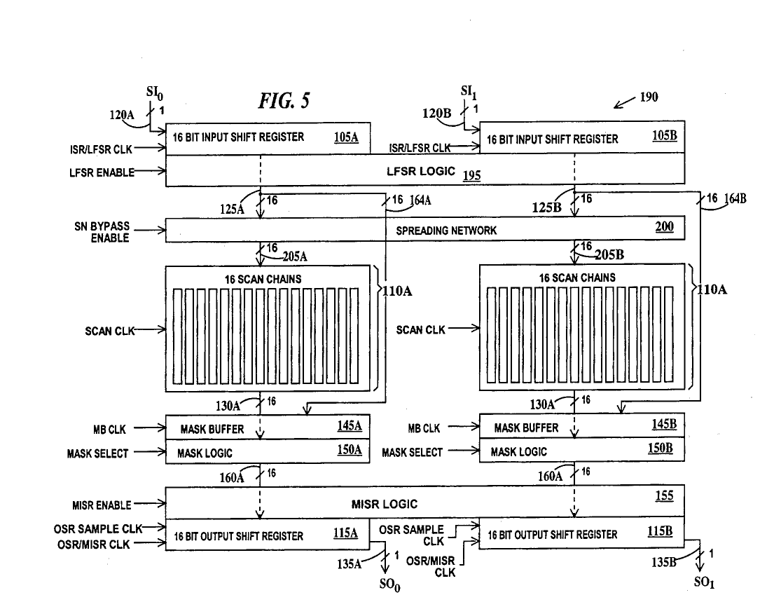

It should be recognized that only a single new data bit is loaded into each input shift register each cycle and the remaining bits are shifted by one bit position. The input shift registers are thus not completely updated for each scan chain shift, resulting in highly correlated test patterns that can create problems as illustrated in FIGS. 3A and 3B and resolved as illustrated in FIGS. 4A and 4B and described infra.

It is also possible to configure the second embodiment of the present invention without first and second mask buffers 145A and 145B and without first and second mask logic 150A and 150B.

FIGS. 3A and 3B are diagrams illustrating a load operation resulting in conflicting values of care bits. FIG. 3A illustrates a 4-bit input shift register 165 and four 8-stage scan chains 171, 172, 173 and 174. A test pattern “K J I H G F E D C B A” is cycled through an input shift register 165 via an input 170 into scan chains 171, 172, 173 and 174. First four clock cycles (only the input shift register clock is active) fill input serial register with the pattern “D C B A.” Then eight additional clock cycles (both the input shift register clock and the scan chain clocks are active) fill up each scan chain 171, 172, 173 and 174. Since each input shift register clock moves a single bit into input shift register 165 but four bits from input shift register 165 into scan chains 171, 172, 173 and 174 (1-bit into each scan chain 171, 172, 173 and 174) a diagonal pattern of is created in scan chains 171, 172, 173 and 174 as illustrated by lines 175.

FIG. 3B illustrates a desired test pattern of 0s and 1s for a test of the combination logic (not shown) coupled to scan chains 171, 172, 173 and 174. Dashes indicate don't care bits while any bit-position with a 0 or a 1 is a care bit. Care bits are bits that test for specific faults in the combinational logic. Generally, few bits are care bits, the vast majority only being used to “fill” the test pattern. These “fill” bits are called don't care bits. Illustrated by ovals 176 in FIG. 3B, the fourth bit-position (from the top) in scan chain 173 contains a 1 while the fifth bit-position of scan chain 172 contains a 0. Since both these bit-positions were filled using bit “J” from the test pattern, a conflict over the care bit values in the input pattern exists. A similar conflict exists between bit-position six of scan chain 173 and bit position seven of scan chain 172. An input pattern of “-0-1-0-0-1-” would establish the correct care bits in scan chain 172. However, the care bits in positions 5 and 7 of scan chain 173 would still be incorrect. Theses conflicts are resolvable by the technique illustrated in FIGS. 4A and 4B and described infra.

FIGS. 4A and 4B are diagrams illustrating a load operation resulting in non-conflicting values of care bits. A test pattern “M L K J I H G F E D C B A” is cycled through input shift register 165 via input 170 into scan chains 171, 172, 173 and 174. The first four clock cycles (only the input shift register clock is active) fill input serial register with the pattern “D C B A.” Note the two extra bit-positions L and M. Then ten additional clock cycles fill up each scan chain 171, 172, 173 and 174. However, instead of cycling both the input scan register clock and the scan chain clocks together for all ten cycles, the scan chain clock is not cycled on the seventh and tenth cycle. Thus a bit still gets loaded into input shift register 170 on the seventh and tenth clock cycles, but no bits are transferred from input shift register 170 to scan chains 171, 172, 173 and 174. Thus the diagonal pattern illustrated in FIG. 3A is as illustrated by lines 175 has been disturbed and the pattern marked by line 180 created.

In FIG. 4B, the input pattern “-0-1-10-10-1-” is seen to produce the desired pattern without conflicts. This solution is relatively easy to implement by simple programming of an automatic test pattern generator (ATPG) that generates the test pattern, without the ATPG program having to solve complex Boolean equations as is required by current test techniques.

For the present example of four 8-stage scan chains, a valid 32-bit test vector (4×8) with correct values for the 8 care bits can be derived from an input pattern of only 13 bits. This is over a 2-fold reduction in the size of the test pattern needed by conventional test methodologies. The size of the input pattern is a result of the number of care bits and care bit “conflicts.” Typical ASICs have a much lower percentage of care bits than the 25% shown in this example, thus the reduction in the size of their test patterns is much greater.

It should be pointed out that some conflicts could also be resolved by only cycling the scan chain clocks while the input shift registers are held off. For example, the particular bit pattern illustrated in FIG. 4B could be achieved by first applying 4 input shift register clock cycles while holding the scan chain clocks off to load a “0 0 1 1” pattern into the input shift register and then cycling the scan clock for 8 cycles with the input shift register clock inactive.

FIG. 5 is a block diagram of a system for testing a logic device according to a third embodiment of the present invention. In FIG. 5 a test system 190, includes (in addition to all the components of test system 140 illustrated in FIG. 2 and described supra) a linear feedback shift register (LFSR) logic 195, a spreading network 200 and buses 205A and 205B. Buses 125A and 125B feed through LFSR logic 195 and spreading network 200 is coupled to first scan chain 110A by bus 205A and coupled to second scan chain 110B by bus 205B. LFSR logic 195, first input shift register 105A and second input shift register 105B are implemented integral to one another. An exemplary integral LSFR logic/input shift register is illustrated in FIG. 7 and described infra.

While LFSR logic is illustrated in FIG. 5, an LFSR is an example of a general class of devices called pseudo-random pattern generators (PRPGs) that are known to persons skilled in the art. Therefore any PRPG logic may be subsituted for LFSR logic 195. Another device that may substituted for LFSR logic 195 is a cellular automata (CA).

ISR CLK of FIGS. 1 and 2 is now ISR/LFSR CLK. ISR/LFSR CLK controls first and second input shift registers 105A and 105B. LFSR logic 195 is controlled by LFSR ENABLE. The two 16-bit words from first and second input shift registers 105A and 105B are concatenated into one 32-bit word bu LFSR logic 195 under the control of an LFSR enable signal LFSR ENABLE. Because of the XOR gate(s) contained in an LFSR, LFSR logic 195 acts as a pseudo random pattern generator (PRPG) by hashing the two 16-bit words within first and second input shift registers 105A and 105B when the LFSR logic is enabled. LFSR logic 195 (if enabled) and first and second input shift registers 105A and 105B or just first and second input shift registers 105A and 105B (if LFSR logic 195 is not enabled) shift a first 16-bit word in into spreading network 200 via bus 125A and shifts a second 16-bit word into spreading network 200 via bus 125B.

LFSRs have a “diagonal repeat” problem similar to that described supra in reference to FIGS. 3A and 3B. Spreading network 200 eliminates this problem. An exemplary spreading network is also illustrated in FIG. 7 and described infra. Spreading network 200 may be bypassed and the two 16 bit words directly passed to scan chains 110A and 110B by buses 205A and 205B respectively, without any changes of bit values or positions.

Test system 190 can be operated in full scan mode as described supra in reference to test system 100 (see FIG. 1) or compressed scan mode as also described supra in reference to test system 140 (see FIG. 2).

It should be understood that the clocking and control signals illustrated in FIGS. 1, 2 and 3 and described supra can come from separate control inputs or can be derived by combination and/or clock gating techniques from a smaller number of shared control and clock inputs. The actual control signal and clock interfaces and decoding depends on chip I/O constraints and the number of different operating modes between which a user wishes to switch. One of the advantages of the present invention is that circuits requiring more scan chains than the number of I/O pins would normally allow can still be tested since multiple can scan chains share the same I/Os. Testing such a constrained system is difficult with conventional ATE.

FIG. 6 is a schematic diagram of an exemplary integral MISR logic/output shift register (OSR) combination. In FIG. 6, MISR/OSR 250 includes a multiplicity of stages 255 interdigitated with a multiplicity of XOR gates 260 in a continuous loop, each stage 255 being coupled between a first input of a previous XOR gate 260 and an output of a subsequent XOR gate 260. There is one XOR gate 260 for each scan chain. A second input of each XOR gate 260 is coupled to a last stage of a different scan chain. Stages 255 comprise the OSR portion of MISR/OSR 250 and XOR gates 260 and a feedback path 262 comprise the MISR logic portion of MISR/OSR 250. The operation of MISR/OSR 250 is readily deducible by a person of ordinary skill in the art, from FIG. 6. Other types of MISRs that may be combined with OSR's that may be substituted for MISR/OSR 250, and their operation, are well known to persons of ordinary skill in the art.

FIG. 7 is a schematic diagram of an exemplary integral linear feedback shift register logic/input shift register (ISR) combination and a typical spreading network. In FIG. 7, LFSR/ISR 270 includes a multiplicity of input stages 275A through 275N, a final stage 280 and a XOR gate 285 arranged in a loop. SIO is coupled to a first input of XOR gate 285. The output of each input stage 275A through 275N is coupled to the input of a subsequent input stage 275A through 275N and a corresponding XOR gate 295A through 295N except the output of input stage 275N is coupled to the input of final stage 280 and to a second input of XOR gate 285 as well as a first input of XOR gate 295N. The output of end stage 280 is coupled to a third input of XOR gate 285. Stages 275A through 275N and 280 comprise the ISR portion of LFSR/ISR 250 and XOR gate 285 and paths 287, 288 and 289 comprise the LFSR logic portion of LFSR/ISR 270. In addition to the single feedback shown in FIG. 6, there are many other feedback configurations that may be used as is well known in the art. In the present example, the output of XOR gate 285 is coupled to the input of input gate 275A.

Exemplary spreading network 290 includes a multiplicity of XOR gates 295. A first input of each XOR gate 295 is coupled to a different stage 275 of LFSR 270. A second input of each XOR gate is coupled to the output of end stage 280 of LFSR 270. The output of each XOR gate 295 is coupled to a first stage of a different scan chain. The operation of LSFR 270 and spreading network 290 are readily deducible by a person of ordinary skill in the art, from FIG. 7. Other forms of spreading networks are well known in the art and may br substituted for the example shown.

Test system 100A may also include any number of additional groups of input shift registers, scan chain sets and output shift registers. A second such group is illustrated in FIG. 8. Test system 100A further includes a second input shift register 105D, a multiplicity of scan chains 110D and a second output shift register 11 SD. Second input shift register 105D receives serial scan in data (SI1), which is a test pattern, from a serial input line 120D. Second input shift register 105D is coupled to scan chains 110D by bus 125D and scan chains 110D are coupled to second output shift register 11 SD by bus 130D Second output shift register 11 SD sends serial scan out data (SO1) to a serial output line 135D. The number of scan chains 110D is not equal to the number of stages in second input shift register 105D or first output shift register 115D. Each stage of first input shift register 105D is coupled to a different first stage of a single scan chain 110D via bus 125D. In the present example, first input shift register 105D comprises 16 stages which include 12 wired stages 121D and 4 un-wired stages 122D. First output shift register 115C comprises 16 stages which include 12 wired stages 123D and 4 un-wired stages 124D. There are 12 scan chains 110D and bus 125D is 12 bits wide.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. An apparatus for testing logic circuits containing a set of scan chains, comprising:
a scan input;
a scan output;
an input shift register coupled between said scan input and said set of scan chains, each first stage of different scan chains of said set of scan chains coupled to a different stage of said input shift register; and
an output shift register coupled between said scan output and said set of scan chains, each last stage of different scan chains coupled to a different stage of said output shift register.

2. The apparatus of claim 1 wherein a number of stages in said input shift register and a number of stages in said output shift register are the same number and a number of scan chains in said set of scan chains is no greater than said same number.

3. The apparatus of claim 1, further including:
first clocking means for shifting data in said input register between stages of said input register;
second clocking means for shifting data between stages of each individual scan chain;
third clocking means for shifting data in said output register between stages of said output register;
means for independently controlling said first clocking means, said second clocking means and said third clocking means.

4. The apparatus of claim 3, further including:
running at a second frequency and said third clocking means running at a third frequency; and said first clocking means running at a first frequency, said second clocking means
wherein said first frequency is a multiple of said second frequency or said third frequency is a multiple of said second frequency or both said first and said third frequencies are multiples of said second frequency.

5. The apparatus of claim 3, further including:
means for selectively cycling said first and said second clocking means in order to load a test pattern into said set of scan chains;
means for selectively cycling said second and said third clocking means in order to unload a response to said test pattern from said set of scan chains; and
means for selectively cycling said first, said second and said third clocking means in order to load another test pattern into said set of scan chains while simultaneously unloading said response to said test pattern from said set of scan chains.

6. The apparatus of claim 5, wherein:
said means for independently controlling said first, second and third clocking means is adapted to change said test pattern; and
said means for independently controlling said first, second and third clocking means is further adapted to change said response to said test pattern.

7. The apparatus of claim 1, further including:
pseudo-random pattern generator logic;
a spreading network;
wherein said pseudo-random pattern generator logic is coupled between said input shift register and a single different stage of said spreading network;
wherein each said single different stage of said spreading network is coupled between said pseudo-random pattern generator logic and a single different first stage of each scan chain of said set of scan chains;
wherein said pseudo-random pattern generator logic is adapted to generate pseudo-random sequences when said scan input is a zero and to generate modified sequences when said scan input is a one; and
wherein said spreader network is adapted to remove data correlations between adjacent positions of said sequences generated by said pseudo-random pattern generator logic.

8. The apparatus of claim 1, further including;
a mask buffer and logic device;
multiple input signature register logic;
wherein each stage of said mask buffer and logic device is coupled between a single different last stage of each scan chain of said set of scan chains and a single different stage of said multiple input signature register logic;
wherein said multiple input signature register logic is coupled to said output shift register; and
wherein said multiple input signature register logic is adapted to compress captured test response data shifted out of said set of scan chains and modified by said mask buffer and logic device.

9. The apparatus of claim 8,
wherein said mask buffer and logic device includes means for logically combining no, one or multiple mask words with data from said set of scan chains; and
wherein said mask words are loaded from said input shift register.

10. The apparatus of claim 8, further including:
one or more additional sets of scan chains;
one or more additional input shift registers, each additional input shift register coupled between a single different scan input of one or more additional scan inputs and a single different set of scan chains of said one or more sets of scan chains, each stage of each additional input shift register coupled to a different first stage of a single scan chain of said one or more additional sets of scan chains;
one or more additional mask buffer and logic devices, each additional mask buffer and logic device coupled between said last stages of said additional scan chain of said set of additional scan chains and said multiple input signature register logic; and
wherein said multiple input signature register logic is further coupled between each additional mask buffer and logic device and one or more additional output shift registers, each additional output shift register coupled to a different additional scan output.

11. The apparatus of claim 10, further including: pseudo-random pattern generator logic coupled between both said input shift register and said additional input shift registers and a spreading network, said spreading network coupled between said pseudo-random pattern generator and each first stage of each scan chain of said set of scan chains and each first stage of each additional scan chain of said one or more additional sets of scan chains.

12. The apparatus of claim 11, further including means for bypassing said multiple input signature register logic and said mask buffer and logic devices or said pseudo-random pattern generator logic or said multiple input signature register logic, said mask buffer and logic devices and said pseudo-random pattern generator logic.

13. A method for testing logic circuits containing a set of scan chains, comprising:
providing a scan input;
providing a scan output;
providing an input shift register coupled between said scan input and said set of scan chains, each first stage of different scan chains of said set of scan chains coupled to a different stage of said input shift register;
providing an output shift register coupled between said scan output and said set of scan chains, each last stage of different scan chains coupled to a different stage of said output shift register;
writing a test pattern to said scan input;
propagating said test pattern through said scan chains; and
reading a resultant pattern at said scan output.

14. The method of claim 13, wherein a number of stages in said input shift register and a number of stages in said output shift register are the same number and a number of scan chains in said set of scan chains is no greater than said same number.

15. The method of claim 13, further including:
shifting data between stages of said input register by a first clocking means;
shifting data between stages of each individual scan chain by a second clocking means;
shifting data between stages of said output register by a third clocking means; and
controlling independently said first clocking means, said second clocking means and said third clocking means.

16. The method of claim 15, further including
running said first clocking means at a first frequency, running said second clocking means at a second frequency and running said third clocking means at a third frequency; and
wherein said first frequency is a multiple of said second frequency or said third frequency is a multiple of said second frequency or both said first and said third frequencies are multiples of said second frequency.

17. The method of claim 15, further including:
cycling selectively said first and said second clocking means in order to load said test pattern into said set of scan chains and cycling selectively said second and said third clocking means in order to unload a response to said test pattern from said set of scan chains or cycling selectively said first, said second and said third clocking means in order to load another test pattern into said set of scan chains while simultaneously unloading said response to said test pattern from said set of scan chains.

18. The method of claim 17,
changing said test pattern by independently controlling said first, second and third clocking means; and
changing said response to said test pattern by independently controlling said first, second and third clocking.

19. The method of claim 13, further including:
providing a pseudo-random pattern generator logic;
providing a spreading network:
wherein said pseudo-random pattern generator logic is coupled between said input shift register and a single different stage of said spreading network;
wherein each said single different stage of said spreading network is coupled between said pseudo-random pattern generator logic and a single different first stage of each scan chain of said set of scan chains;
generating in said pseudo-random pattern generator logic, pseudo-random sequences when said scan input is a zero and generating modified sequences when said scan input is a one; and
removing in said spreader network, data correlations between adjacent positions of said sequences generated by said pseudo-random pattern generator logic.

20. The method of claim 13, further including:
providing a mask buffer and logic device;
providing multiple input signature register logic;
wherein each stage of said mask buffer and logic device is coupled between a single different last stage of each scan chain of said set of scan chains and a single different stage of said multiple input signature register logic;
wherein said multiple input signature register logic is coupled to said output shift register;
preventing in said mask buffer and logic device, unknown values to be shifted into said multiple input signature register logic; and
compressing in said multiple input signature register logic, captured test response data shifted out of said set of scan chains and modified by said mask buffer and logic device.

21. The method of claim 20, further including:
combining within said mask buffer and logic device no, one or multiple mask words with data from said set of scan chains; and
wherein said mask words are loaded from said input shift register.

22. The method of claim 20, further including:
providing one or more additional sets of scan chains;
providing one or more additional input shift registers, each additional input shift register coupled between a single different scan input of one or more additional scan inputs and a single different set of scan chains of said one or more sets of scan chains, each stage of each additional input shift register coupled to a different first stage of a single scan chain of said one or more additional sets of scan chains;
providing one or more additional mask buffer and logic devices, each additional mask buffer and logic device coupled between said last stages of said additional scan chain of said set of additional scan chains and said multiple input signature register logic; and
wherein said multiple input signature register logic is further coupled between each additional mask buffer and logic device and one or more additional output shift registers, each additional output shift register coupled to a different additional scan output.

23. The method of claim 22, further including:
providing a pseudo-random pattern generator logic coupled between both said input shift register and said additional input shift registers and a spreading network, said spreading network coupled between said pseudo-random pattern generator and each first stage of each scan chain of said set of scan chains and each first stage of each additional scan chain of said one or more additional sets of scan chains.

24. The method of claim 23, further including:
bypassing said multiple input signature register logic and said mask buffer and logic devices or said pseudo-random pattern generator logic or said multiple input signature register logic, said mask buffer and logic devices and said pseudo-random pattern generator logic.
